(19) United States
(12) Patent Application Publication
(10) Pub. No.: US 2011/0208453 A1
(43) Pub. Date: Aug. 25, 2011

(54) CIRCUIT-BASED METHOD FOR ESTIMATING BATTERY CAPACITY

(76) Inventors: Song Ci, Omaha, NE (US); Jiucai Zhang, Omaha, NE (US)

(21) Appl. No.: 13/033,519

(22) Filed: Feb. 23, 2011

Related U.S. Application Data
(60) Provisional application No. 61/307,097, filed on Feb. 23, 2010.

(51) Int. Cl. G01R 31/36; G06F 19/00

(52) U.S. Cl. 702/63

(57) ABSTRACT

A method for providing state of charge (SOC) estimations is disclosed. The method may comprise: receiving a battery having a nominated capacity; measuring an initial SOC of the battery; discharging the battery and measuring a sequence of time-based discharge characteristics; measuring a total operating time and a total consumed capacity; providing a set of relationship equations derived from a circuit-based battery model having a variable capacitor; utilizing a computing module to perform data fitting of the set of relationship equations based on: the initial SOC, the nominated capacity, the total operating time, the total consumed capacity, and the sequence of discharge characteristics, the computing module being configured for determining values for a plurality of parameters of the set of relationship equations through said data fitting; and obtaining a remaining capacity estimation equation based on the set of relationship equations after the values for the plurality of parameters are determined.

### CROSS-REFERENCE TO RELATED APPLICATIONS

The present application claims the benefit under 35 U.S.C. §119(e) of U.S. Provisional Application Ser. No. 61/307,097, filed Feb. 23, 2010. Said U.S. Provisional Application Ser. No. 61/307,097 is hereby incorporated by reference in its entirety.

### TECHNICAL FIELD

The disclosure generally relates to the field of batteries, particularly to a circuit-based method for estimating battery capacity.

### BACKGROUND

Various types of batteries may be utilized in products such as laptops, battery-powered electric vehicles, battery energy storage systems or the like. The ability to accurately estimate the state of charge (SOC), which may also be referred to as the remaining capacity, of a battery may be crucial for power management as well as battery maintenance in these products. However, SOC of a given battery usually may not be readily available or directly determined. Therefore, various battery models have been proposed for SOC estimations.

In general, existing battery models may include chemical models, analytical models, and circuit-based models. In chemical models, differential equations may be utilized to capture complex electrical-chemical processes within a particular type of battery and provide relatively accurate characterizations of that particular type. However, chemical models require intensive computations to solve interdependent partial differential equations. In addition, due to lack of battery model parameters such as battery structure and chemical composition, chemical models are difficult to be configured and utilized.

Analytical models have been developed for SOC estimations. An analytical model may utilize a mathematical representation to approximate a battery performance. While the analytical models may reduce the computational complexity compared to the chemical models, they ignore circuit features such as voltage and internal resistance within a battery, making the analytical models infeasible for multi-cell battery design and analysis as well as circuit simulation.

In circuit-based models, battery nonlinear circuit behaviors may be emulated by using capacitors, voltage and voltage controlled voltage resources, and resistors from a circuit analysis point of view. Therefore, a circuit-based model may capture complex battery properties, which may then be implemented in electronic design automation (EDA) tools at different levels of abstraction. However, existing circuit-based models may not estimate the impact of nonlinear behaviors on battery available capacity, which may lead to an inaccurate prediction of remaining battery capacity.

Therefore, a new circuit-based battery model is needed to capture the battery circuit features and nonlinear battery capacity effects (e.g., the recovery effect or the like). Furthermore, methods/processes are also needed for providing SOC estimations based on the new circuit-based battery model.

### SUMMARY

The present disclosure is directed to a method and system for providing SOC estimations (may also be referred to as remaining capacity estimation) for batteries. The method is developed based on a circuit-based battery model having a variable/adjustable capacitor. The variable capacitor may allow the circuit-based battery model to capture both battery circuit features and nonlinear battery capacity effects to provide a more comprehensive and accurate model.

The method may include a measurement process and a data fitting process. The measurement process may include: receiving a battery having a manufacturer nominated capacity; measuring an initial state of charge (SOC) of the battery; discharging the battery and measuring a sequence of time-based discharge characteristics of the battery during the discharge of the battery; measuring a total operating time of the battery and a total consumed capacity. The data fitting process may include: providing a set of relationship equations, the set of relationship equations being derived from a circuit-based battery model having a variable capacitor; utilizing a computing module to perform data fitting of the set of relationship equations based on: the initial SOC, the manufacturer nominated capacity, the total operating time, the total consumed capacity, and the sequence of time-based discharge characteristics, the computing module being configured for determining values for a plurality of parameters of the set of relationship equations through said data fitting; and obtaining a remaining capacity estimation equation based on the set of relationship equations after the values for the plurality of parameters are determined through said data fitting.

The method and system of the present disclosure may be utilized to provide remaining capacity estimation for multi-cell batteries. Each multi-cell battery may have a plurality of battery cells connected in accordance to a cell topology. The method may include: determining at least one battery type utilized in the multi-cell battery; obtaining a remaining capacity estimation equation for each one of the at least one battery type; mapping the cell topology to at least one of: a series system having a plurality of battery components connected in series, and a parallel system having a plurality of battery components connected in parallel; and estimating the remaining capacity for the multi-cell battery, wherein the remaining capacity for the multi-cell battery is the minimum of the remaining capacities of the plurality of battery components when the plurality of battery components are connected in series, and the remaining capacity for the multi-cell battery is the sum of the remaining capacities of the plurality of battery components when the plurality of battery components are connected in parallel.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF THE DRAWINGS

The numerous advantages of the disclosure may be better understood by those skilled in the art by reference to the accompanying figures in which:

FIG. 1 is a flow diagram illustrating a method for providing remaining capacity estimations;

FIG. 2 is an illustration depicting a new circuit-based battery model;

FIG. 3 is a block diagram illustrating a system for providing remaining capacity estimations;

FIGS. 4A through 4C are illustrations depicting cell topology abstractions; and

FIG. 5 is a flow diagram illustrating a method for providing remaining capacity estimation for a multi-cell battery.

### DETAILED DESCRIPTION

Reference will now be made in detail to the subject matter disclosed, which is illustrated in the accompanying drawings.

The present disclosure is directed to a method and system for providing SOC estimations (may also be referred to as remaining capacity estimation) for batteries. The method and system in accordance with the present disclosure are developed based on a circuit-based battery model having a variable/adjustable capacitor. The variable capacitor may allow the circuit-based battery model to capture both battery circuit features and nonlinear battery capacity effects to provide a more comprehensive and accurate model.

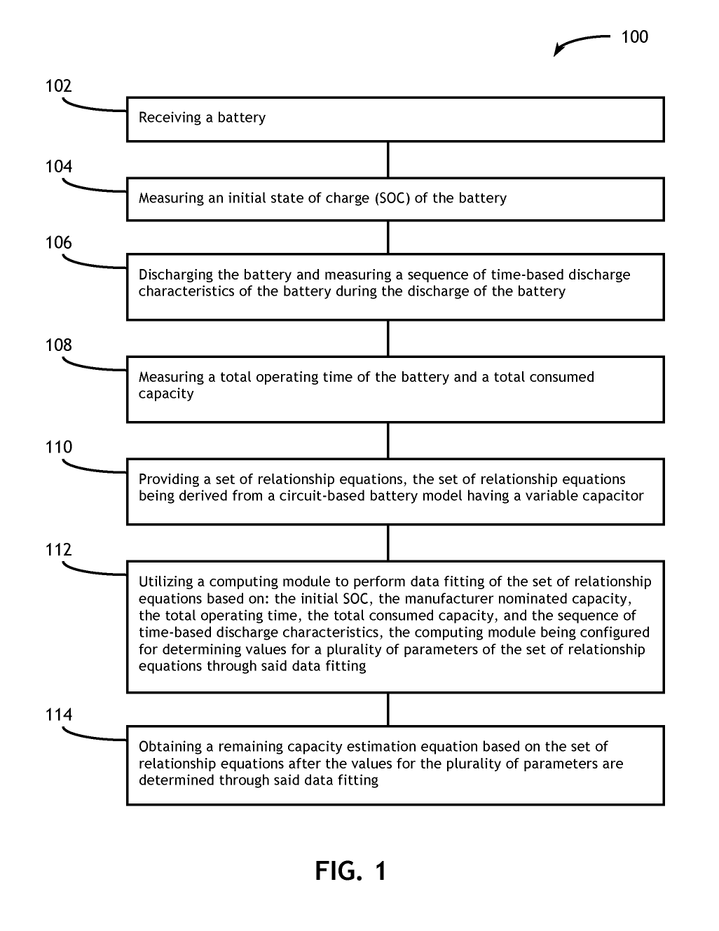

Referring to FIG. 1, a method 100 for providing remaining capacity estimation for single-cell batteries is shown. The method 100 may include a measurement process and a data fitting process. During the measurement process, the method 100 may discharge a sample battery and measure various performance attributes associated with this sample battery. Upon completion of the measurement process, the measured attributes may be applied to a set of relationship equations and a battery model describing the behaviors of the sample battery may be obtained. The obtained battery model may then be utilized for estimating remaining capacities for any batteries of the same type as the sample battery.

In one embodiment, step 102 may receive a fully charged sample battery that represents a particular type of battery. Various performance attributes associated with this sample battery may then be measured during the measurement process. For example, step 104 may measure the initial SOC of the sample battery (φ^{C}). In addition, the full capacity of the sample battery (c^{f}) may also be measured. It is understood, however, that each type of battery may have a manufacturer specified nominated capacity, which may be utilized to represent the full capacity (c^{f}).

Further measurements may be taken when the sample battery is being discharged. For instance, step 106 may start discharging the battery and measuring a sequence of time-based discharge characteristics of the battery until the battery is completely discharged to cutoff voltage, which is specified by battery manufacturer. A predetermined time interval may be utilized to control the measurement of such discharge characteristics. In one embodiment, the discharge characteristics of the battery may be continually measured while the battery load is disconnected for 10 seconds every ten minutes during the discharge process. When the battery has a low SOC (e.g., φ^{C}<0.2), the discharge characteristics of the battery may be continually measured while the battery load is disconnected for 10 seconds every one minute during the discharge process. The discharge characteristics measured may include the discharge current (I^{C}), the output voltage (V^{C}) and the accumulated consumed capacity (α^{A}).

Once the sample battery is completely discharged, step 108 may take final measurements of the total operating time of the battery (L) as well as the total consumed capacity (α^{f}). This completes the measurement process of the method 100.

The data fitting process of the method 100 may commence upon completion of the measurement process. The data fitting process may apply the measured attributes to a set of relationship equations in order to obtain a battery model that describes the behaviors of the sample battery.

In one embodiment, the measurements are applied to the set of relationship equations in step 110. The set of relationship equations in accordance with the present disclosure are derived from a circuit-based battery model having a variable capacitor. The variable capacitor allows the circuit-based battery model to nonlinear battery capacity effects (e.g., temperature effects, aging effects, recovery effects or the like) to provide a more comprehensive and accurate model.

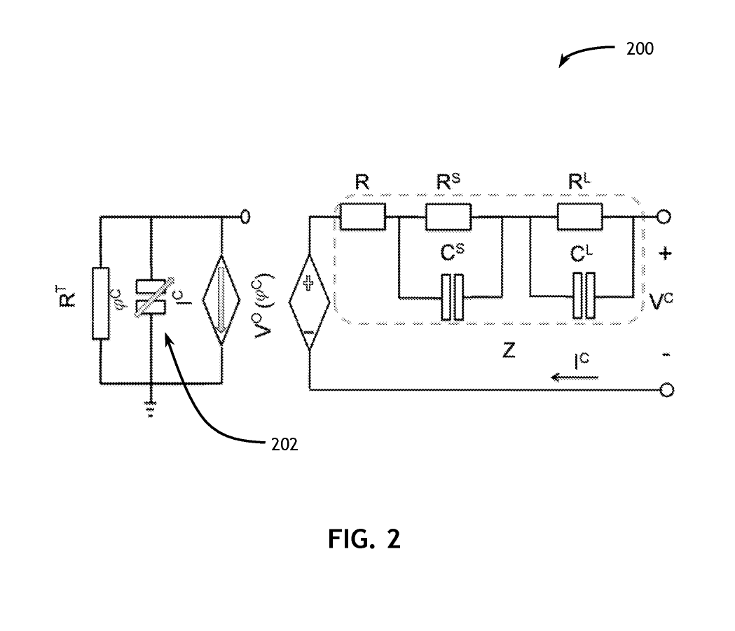

An exemplary circuit-based battery model 200 having a variable capacitor 202 is depicted in FIG. 2. This model is divided into two parts by the voltage controlled voltage sources, which is used to capture the nonlinear relationship between battery open-circuit voltage and state of charge. In the left portion as illustrated in the figure, the nonlinear capacitor (e.g. φ^{C}) is used to model battery nonlinear capacity effects including temperature effects, aging effects, recovery effects. A large resistance is adopted to capture the self-discharge process of the battery. The right portion as illustrated in the figure utilizes nonlinear resistors and capacitors to capture the nonlinear circuit characteristics of the battery. The RC Network (e.g. R^{L} & C^{L}, R^{S} & C^{S}) emulates the transient voltage response. The resistance (e.g. R) is used to capture internal resistance of battery, which can also model effect of temperature and ages on the battery performance.

The relationship equations in accordance with the present disclosure are derived from the circuit-based battery model 200. Such relationship equations may be utilized to mathematically describe the relationships between various characteristics of a battery. In one embodiment, the relationship equations for a battery may be expressed as follows:

$$\{ \begin{matrix}{α}^{A} ( {I}^{C} , β , L , {t}_{s} , {t}_{e} ) = {I}^{C} F ( L , {t}_{s} , {t}_{e} , β ) \\ F ( L , {t}_{s} , {t}_{e} , β ) = {t}_{s} - {t}_{e} + 2 {\sum }_{m = 1}^{∞} \frac{{e}^{- {β}^{2} {m}^{2} ( L - {t}_{s} )} - {e}^{- {β}^{2} {m}^{2} ( L - {t}_{e} )}}{{β}^{2} {m}^{2}} \\ {ϕ}^{C} = 1 - \frac{{α}^{A}}{{c}^{f}} \\ {V}^{o} ( {ϕ}^{C} ) = {a}_{1} {e}^{{a}_{2} {ϕ}^{c}} + {a}_{3} {ϕ}^{C} + {a}_{4} {ϕ}^{{C}^{2}} + {a}_{5} {ϕ}^{{C}^{3}} + {a}_{6} \\ R ( {ϕ}^{C} ) = {b}_{1} {e}^{{b}_{2} {ϕ}^{c}} + {b}_{3} {ϕ}^{C} + {b}_{4} {ϕ}^{{C}^{2}} + {b}_{5} {ϕ}^{{C}^{3}} + {b}_{6} \\ {R}^{S} ( {ϕ}^{C} ) = {d}_{1} {e}^{{d}_{2} {ϕ}^{c}} + {d}_{3} \\ {C}^{S} ( {ϕ}^{C} ) = {f}_{1} {e}^{{f}_{2} {ϕ}^{c}} + {f}_{3} \\ {R}^{L} ( {ϕ}^{C} ) = {g}_{1} {e}^{{g}_{2} {ϕ}^{c}} + {g}_{3} \\ {C}^{L} ( {ϕ}^{C} ) = {l}_{1} {e}^{{l}_{2} {ϕ}^{c}} + {l}_{3}\end{matrix}$$

where

V^{C} is the output voltage;

φ^{C} is the initial SOC of the battery;

α^{A} is the accumulated consumed capacity;

I^{C} is the discharge current rate;

β² is a constant related to the diffusion rate within battery; the larger the β², the faster the battery diffusion rate may be, thus the less the discharging loss;

c^{f} is the manufacture nominated capacity of the battery;

L is the total operating time of the battery;

tₛ and tₑ are the start time and end time of a discharge period, respectively;

m is a user defined complexity factor that determines the computational complexity and accuracy of the model, a typical value for m may be 10;

V^{o} is the open-circuit voltage;

R is the internal resistance of the battery;

R^{S} is the short-transient resistance;

C^{S} is the short-transient capacitance;

R^{L} is the long-transient resistance; and

C^{L} is the long-transient capacitance.

a₁˜a₆, b₁˜b₆, d₁˜d₃, f₁˜f₃, g₁˜g₃, and l₁˜l₃ are coefficients of the relationship equations.

As defined in the relationship equations above, the accumulated capacity is denoted by an analytical expression to capture the battery recovery effect. The consumed capacity α^{A}(I^{C},β,L,tₛ,tₑ), which is dissipated during the discharge period [tₛ,tₑ] at the discharge current I^{C}, is written as:

$$\{ \begin{matrix}{α}^{A} ( {I}^{C} , β , L , {t}_{s} , {t}_{e} ) = {I}^{C} F ( L , {t}_{s} , {t}_{e} β ) \\ F ( L , {t}_{s} , {t}_{e} , β ) = {t}_{s} - {t}_{e} + 2 {\sum }_{m = 1}^{∞} \frac{{e}^{- {β}^{2} {m}^{2} ( L - {t}_{s} )} - {e}^{- {β}^{2} {m}^{2} ( L - {t}_{e} )}}{{β}^{2} {m}^{2}}\end{matrix}$$

In this equation, the first term I^{C}×(tₛ−tₑ) is the consumed capacity by the load I^{C} during the discharge period [tₛ,tₑ]; the second term

$${I}^{C} \times 2 {\sum }_{m = 1}^{∞} \frac{{e}^{- {β}^{2} {m}^{2} ( L - {t}_{s} )} - {e}^{- {β}^{2} {m}^{2} ( L - {t}_{e} )}}{{β}^{2} {m}^{2}}$$

is the amount of discharging loss due to the current effect, which is the maximum recoverable battery capacity at tₑ. It can be observed that the discharge loss may increase as the discharge current increases.

Based on the relationship equations defined above and the data measured in the previous steps, step 112 may utilize a computing module (e.g., a computer processor or the like) to perform various data fitting techniques to determine the values of the unknown attributes and parameters expressed in the relationship equations. In the example above, the initial SOC (φ^{C}), the full capacity (c^{f}), the total operating time (L), the total consumed capacity (α^{f}) and the series of discharge characteristics (including I^{C}, V^{C} and α^{A}) are known and are applied to the relationship equations above. All other attributes and parameters may be determined through data fitting.

Once the values for the other attributes and parameters are determined, step 114 may then utilize the relationship equations to obtain a remaining capacity estimation equation for this particular type of battery. For instance, based on the relationship equations defined above, when a fully charged battery of the same type is discharged over time τ={t₀,t₁,L t_{N}}, its remaining capacity (α^{C}) may be estimated as:

$${α}^{C} = {α}^{f} - {\sum }_{i = 0}^{N} {α}^{A} ( {I}_{i}^{C} , β , L , {t}_{i - 1} , {t}_{i} ) .$$

That is, for any given battery of the same type as the sample battery, once the its discharge time since the last full charge is determined, this discharge time may be utilized as input to the remaining capacity estimation equation above to estimate the remaining capacity of the given battery.

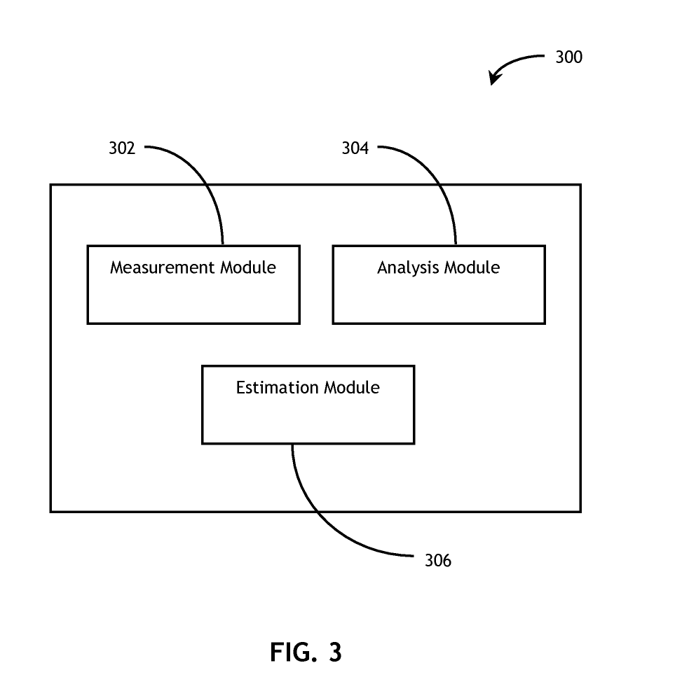

Referring to FIG. 3, an illustration depicting a system 300 for providing remaining capacity estimation for any given type of battery is shown. The system 300 may include a measurement module 302 for measuring performance of a sample battery that represents a specific type of battery. For example, the measurement module 302 may first measure the full capacity and the initial state of charge (SOC) of the sample battery. The measurement module 302 may then start discharging the battery and measuring a sequence of time-based discharge characteristics of the battery until the battery is completely discharged. In addition, when the sample battery is completely discharged, the measurement module 302 may take final measurements of the total operating time of the sample battery as well as the total consumed capacity.

The system 300 may further include an analysis module 304 and an estimation module 306. The analysis module 304 may be configured for analyzing the performance of the battery. For example, the measurements received from the measurement modules 302 may be applied to a set of relationship equations in order to obtain a battery model that describes the behaviors of the sample battery. The estimation module 306 may subsequently obtain the remaining capacity estimation equation for this type of battery based on the battery model as previously described.

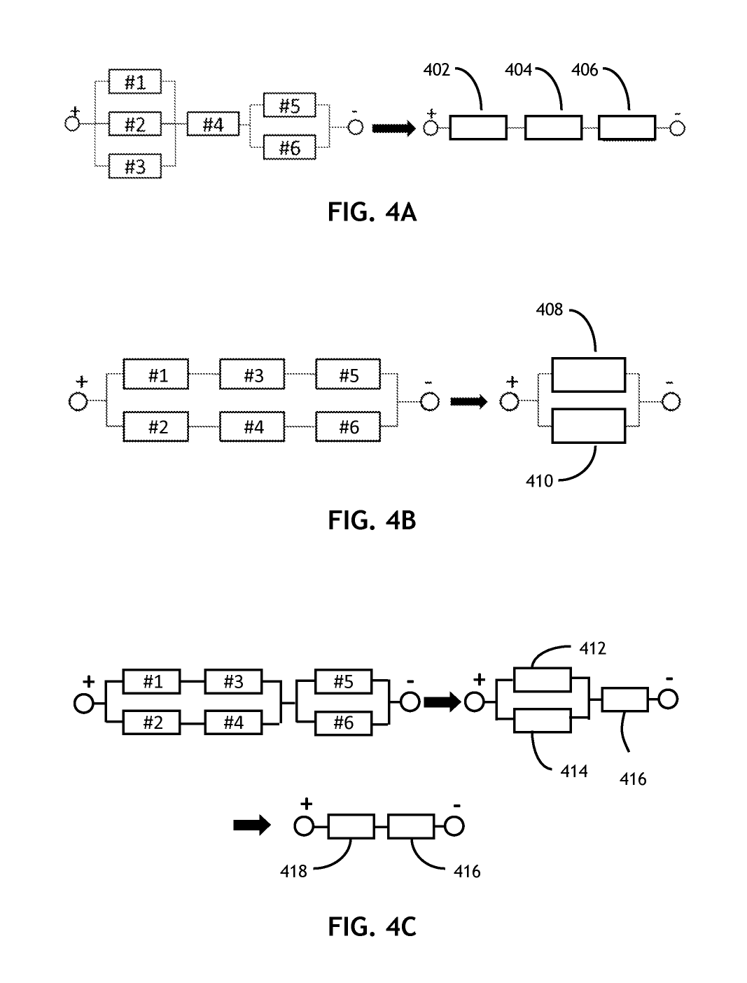

The method and system of the present disclosure may be utilized to provide remaining capacity estimation for multi-cell batteries. It is contemplated that an arbitrary multi-cell connection/topology may be abstracted as either a series system or a parallel system, where each element is a group of cells in series, parallel, or hybrid series-and-parallel connection. A hybrid series-and-parallel connection may be recursively abstracted as either series or parallel connection. That is, any given cell connection in a multi-cell battery may be abstracted out to two basic cell connections: cell strings in series connection and cell strings in parallel connection, as illustrated in FIGS. 4A, 4B and 4C.

As illustrated in FIG. 4A, a hybrid series-and-parallel connection including battery 1 through battery 6 may be mapped to multiple cell strings in series connection. In this example, cell 1 through cell 3 are mapped to cell string 402, cell 4 is mapped to cell string 404, and cell 5 and cell 6 are mapped to cell string 406. In another example as illustrated in FIG. 4B, another hybrid series-and-parallel connection may be mapped to multiple cell strings in parallel connection. In this example, cell 1, cell 3 and cell 5 are mapped to cell string 408 while cell 2, cell 4 and cell 6 are mapped to cell string 410.

It is contemplated that the abstractions depicted in FIGS. 4A and 4B are merely exemplary. Such abstractions may be applied to any arbitrary multi-cell topology without departing from the spirit and scope of the present disclosure. It is further contemplated that such abstractions may be applied recursively as illustrated in FIG. 4C, in which cell string 418 is a further abstraction of cell strings 412 and 414.

To obtain the remaining capacity estimation for a multi-cell battery, the remaining capacity estimation equation for each individual cell included in the multi-cell topology may need to be obtained first. The remaining capacity estimation equation for each individual cell may be obtained utilizing the method 100 as previously described. It is understood that if the cells included in a multi-cell battery are of the same type, then method 100 may only need to be applied once to any one of the cells. Otherwise, method 100 may need to be applied once for each type of cell involved in the multi-cell battery.

Once the remaining capacity estimation equation for each individual cell included in a multi-cell topology is obtained, the remaining capacity for the multi-cell battery may then be determined. In one embodiment, the remaining capacity of two or more cells (or cell strings) connected in series may be determined as the minimum of their respective remaining capacities. On the other hand, the remaining capacity of two or more cells (or cell strings) connected in parallel may be determined as the sum of their respective remaining capacities.

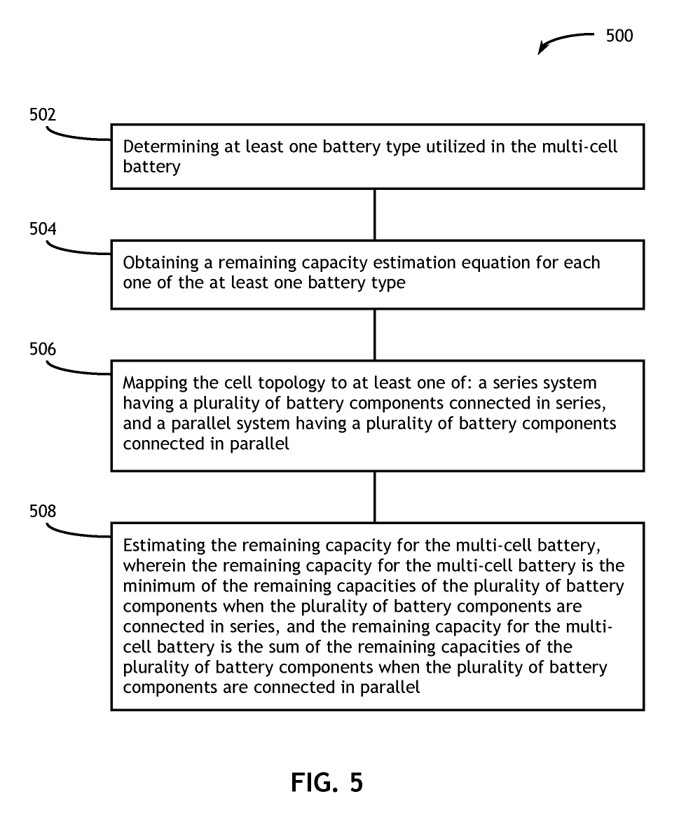

Referring to FIG. 5, a method 500 for providing remaining capacity estimation for a multi-cell battery is shown. The multi-cell battery may include a plurality of battery cells connected in accordance to a cell topology. Step 502 may determine the types of battery cells utilized in the multi-cell battery. Step 504 may obtain a remaining capacity estimation equation for each particular type of battery cell utilized. The remaining capacity estimation equation for each particular type of battery cell may be obtained utilizing the method 100 as previously described.

Step 506 may map the cell topology to either a series system or a parallel system as previously described. A series system may include multiple battery components connected in series, whereas a parallel system may include multiple battery components connected in parallel. The term battery component may refer to any single unit within a given level of abstraction. For example, referring to the multi-cell battery depicted in FIG. 4C, the cell topology without any abstraction may include six battery components, namely cells 1 through 6; the cell topology with intermediate level of abstraction may include three battery components, namely cell strings 412, 414 and 416; and the cell topology with higher level of abstraction may include two battery components, namely cell strings 418 and 416.

Step 508 may estimate the remaining capacity for the multi-cell battery. The remaining capacity for the multi-cell battery may be determined as the minimum remaining capacity among the battery components when the battery components are connected in series. On the other hand, the remaining capacity for the multi-cell battery may be determined as the sum of the remaining capacities of battery components when the battery components are connected in parallel. It is contemplated that in cases where multiple levels of topology abstraction (as illustrated in FIG. 4C) is utilized, step 508 may be applied recursively in order to obtain the remaining capacity for the top level abstraction.

Utilizing method 500, for example, the remaining capacity for the multi-cell battery of FIG. 4A may be determined as the minimum of the remaining capacities of cell strings 402, 404 and 406 (cell strings in series connection). Furthermore, the remaining capacity for cell string 402 may be determined as the sum of the remaining capacities of cell 1, cell 2 and cell 3 (cells in parallel connection); the remaining capacity for cell string 404 may be determined as the remaining capacity of cell 4; and the remaining capacity for cell string 406 may be determined as the sum of the remaining capacities of cell 5 and cell 6 (cells in parallel connection).

In another example, the remaining capacity for the multi-cell battery of FIG. 4B may be determined as the sum of the remaining capacities of cell strings 408 and 410 (cell strings in parallel connection). Furthermore, the remaining capacity for cell string 408 may be determined as the minimum of the remaining capacities of cell 1, cell 3 and cell 5 (cells in series connection); the remaining capacity for cell string 410 may be determined as the minimum of the remaining capacities of cell 2, cell 4 and cell 6 (cells in series connection).

In still another example, the remaining capacity for the multi-cell battery of FIG. 4C may be determined as the minimum of the remaining capacities of cell strings 418 and 416 (cell strings in series connection). Furthermore, the remaining capacity for cell string 418 may be determined as the sum of the remaining capacities of cell strings 412 and 414 (cell strings in parallel connection); the remaining capacity for cell string 412 may be determined as the minimum of the remaining capacities of cell 1 and cell 3 (cells in series connection); the remaining capacity for cell string 414 may be determined as the minimum of the remaining capacities of cell 2 and cell 4 (cells in series connection); and the remaining capacity for cell string 416 may be determined as the sum of the remaining capacities of cell 5 and cell 6 (cells in parallel connection).

It is understood that the present disclosure is not limited to any underlying implementing technology. The present disclosure may be implemented utilizing any combination of software and hardware technology. The present disclosure may be implemented using a variety of technologies without departing from the scope and spirit of the invention or without sacrificing all of its material advantages.

It is understood that the specific order or hierarchy of steps in the processes disclosed is an example of exemplary approaches. Based upon design preferences, it is understood that the specific order or hierarchy of steps in the processes may be rearranged while remaining within the scope of the present invention. The accompanying method claims present elements of the various steps in a sample order, and are not meant to be limited to the specific order or hierarchy presented.

It is believed that the present disclosure and many of its attendant advantages will be understood by the foregoing description, and it will be apparent that various changes may be made in the form, construction, and arrangement of the components thereof without departing from the scope and spirit of the invention or without sacrificing all of its material advantages. The form herein before described being merely an explanatory embodiment thereof, it is the intention of the following claims to encompass and include such changes.

What is claimed is:

1. A method for providing remaining capacity estimations, the method comprising:
receiving a battery, the battery having a manufacturer nominated capacity;
measuring an initial state of charge (SOC) of the battery;
discharging the battery and measuring a sequence of time-based discharge characteristics of the battery during the discharge of the battery;
measuring a total operating time of the battery and a total consumed capacity;
providing a set of relationship equations, the set of relationship equations being derived from a circuit-based battery model having a variable capacitor;
utilizing a computing module to perform data fitting of the set of relationship equations based on: the initial SOC, the manufacturer nominated capacity, the total operating time, the total consumed capacity, and the sequence of time-based discharge characteristics, the computing module being configured for determining values for a plurality of parameters of the set of relationship equations through said data fitting; and
obtaining a remaining capacity estimation equation based on the set of relationship equations after the values for the plurality of parameters are determined through said data fitting.

2. The method of claim 1, further comprising:
receiving a second battery, the second battery being of the same type as the first mentioned battery;
determining a discharge time since last full charge of the second battery; and
estimating a remaining capacity of the second battery based on the remaining capacity estimation equation and the discharge time since last full charge.

3. The method of claim 1, wherein the sequence of time-based discharge characteristics of the battery comprises as least one of:
a sequence of time-based discharge current of the battery;
a sequence of time-based output voltage of the battery; and
a sequence of time-based accumulated consumed capacity.

4. The method of claim 3, wherein the set of relationship equations are defined as:
$$\{ \begin{matrix}{α}^{A} ( {I}^{C} , β , L , {t}_{s} , {t}_{e} ) = {I}^{C} F ( L , {t}_{s} , {t}_{e} , β ) \\ F ( L , {t}_{s} , {t}_{e} , β ) = {t}_{s} - {t}_{e} + 2 {\sum }_{m = 1}^{∞} \frac{{e}^{- {β}^{2} {m}^{2} ( L - {t}_{s} )} - {e}^{- {β}^{2} {m}^{2} ( L - {t}_{e} )}}{{β}^{2} {m}^{2}} \\ {ϕ}^{c} = 1 - \frac{{α}^{A}}{{c}^{f}} \\ {V}^{o} ( {ϕ}^{C} ) = {a}_{1} {e}^{{a}_{2} {ϕ}^{c}} + {a}_{3} {ϕ}^{C} + {a}_{4} {ϕ}^{{C}^{2}} + {a}_{5} {ϕ}^{{C}^{3}} + {a}_{6} \\ R ( {ϕ}^{C} ) = {b}_{1} {e}^{{b}_{2} {ϕ}^{c}} + {b}_{3} {ϕ}^{C} + {b}_{4} {ϕ}^{{C}^{2}} + {b}_{5} {ϕ}^{{C}^{3}} + {b}_{6} \\ {R}^{S} ( {ϕ}^{C} ) = {d}_{1} {e}^{{d}_{2} {ϕ}^{c}} + {d}_{3} \\ {C}^{S} ( {ϕ}^{C} ) = {f}_{1} {e}^{{f}_{2} {ϕ}^{c}} + {f}_{3} \\ {R}^{L} ( {ϕ}^{C} ) = {g}_{1} {e}^{{g}_{2} {ϕ}^{c}} + {g}_{3} \\ {C}^{L} ( {ϕ}^{C} ) = {l}_{1} {e}^{{l}_{2} {ϕ}^{c}} + {l}_{3}\end{matrix}$$
and wherein the values for the initial SOC (φ^{C}), the manufacturer nominated capacity (c^{f}), the discharge current (I^{C}), the output voltage (V^{C}), the accumulated consumed capacity (α^{A}), the total operating time (L) and the total consumed capacity (α^{f}) are measured, and the values for all other parameters expressed in the set of relationship equations are obtained through data fitting.

5. The method of claim 4, wherein the remaining capacity estimation equation is defined as:
$$remaining capacity {α}^{C} = {α}^{f} - {\sum }_{i = 0}^{N} {α}^{A} ( {I}_{i}^{C} , β , L , {t}_{i - 1} , {t}_{i} ) .$$

6. The method of claim 1, wherein the battery is fully charged when the battery is received, and the battery is fully discharged when said discharge of the battery is completed.

7. A system for providing remaining capacity estimation for a given type of battery, the system comprising:
a measurement module for measuring performance of a battery which represents the given type of battery, the measurement module configured for:
measuring a full capacity of the battery and an initial state of charge (SOC) of the battery;
discharging the battery and measuring a sequence of time-based discharge characteristics of the battery during the discharge of the battery; and
measuring a total operating time of the battery and a total consumed capacity;
an analysis module for analyzing the performance of the battery, the analysis module configured for:
providing a set of relationship equations, the set of relationship equations being derived from a circuit-based battery model having a variable capacitor;
performing data fitting of the set of relationship equations based on: the initial SOC, the manufacturer nominated capacity, the total operating time, the total consumed capacity, and the sequence of time-based discharge characteristics; and
determining values for a plurality of parameters of the set of relationship equations through said data fitting; and
an estimation module for obtaining a remaining capacity estimation equation based on the set of relationship equations after the values for the plurality of parameters are determined through said data fitting.

8. The system of claim 7, wherein the estimation module is further configured for:
receiving another battery of the given type of battery;
determining a discharge time since last full charge of the other battery; and
estimating a remaining capacity of the other battery based on the remaining capacity estimation equation and the discharge time since last full charge.

9. The system of claim 7, wherein the sequence of time-based discharge characteristics of the battery comprises as least one of:
a sequence of time-based discharge current of the battery;
a sequence of time-based output voltage of the battery; and
a sequence of time-based accumulated consumed capacity.

10. The system of claim 9, wherein the set of relationship equations are defined as:
$$\{ \begin{matrix}{α}^{A} ( {I}^{C} , β , L , {t}_{s} , {t}_{e} ) = {I}^{C} F ( L , {t}_{s} , {t}_{e} , β ) \\ F ( L , {t}_{s} , {t}_{e} , β ) = {t}_{s} - {t}_{e} + 2 {\sum }_{m = 1}^{∞} \frac{{e}^{- {β}^{2} {m}^{2} ( L - {t}_{s} )} - {e}^{- {β}^{2} {m}^{2} ( L - {t}_{e} )}}{{β}^{2} {m}^{2}} \\ {ϕ}^{C} = 1 - \frac{{α}^{A}}{{c}^{f}} \\ {V}^{o} ( {ϕ}^{C} ) = {a}_{1} {e}^{{a}_{2} {ϕ}^{c}} + {a}_{3} {ϕ}^{C} + {a}_{4} {ϕ}^{{C}^{2}} + {a}_{5} {ϕ}^{{C}^{3}} + {a}_{6} \\ R ( {ϕ}^{C} ) = {b}_{1} {e}^{{b}_{2} {ϕ}^{c}} + {b}_{3} {ϕ}^{C} + {b}_{4} {ϕ}^{{C}^{2}} + {b}_{5} {ϕ}^{{C}^{3}} + {b}_{6} \\ {R}^{S} ( {ϕ}^{C} ) = {d}_{1} {e}^{{d}_{2} {ϕ}^{c}} + {d}_{3} \\ {C}^{S} ( {ϕ}^{C} ) = {f}_{1} {e}^{{f}_{2} {ϕ}^{c}} + {f}_{3} \\ {R}^{L} ( {ϕ}^{C} ) = {g}_{1} {e}^{{g}_{2} {ϕ}^{c}} + {g}_{3} \\ {C}^{L} ( {ϕ}^{C} ) = {l}_{1} {e}^{{l}_{2} {ϕ}^{c}} + {l}_{3}\end{matrix}$$
and wherein the values for the initial SOC (φ^{C}), the manufacturer nominated capacity (c^{f}), the discharge current (I^{C}), the output voltage (V^{C}), the accumulated consumed capacity (α^{A}), the total operating time (L) and the total consumed capacity (α^{f}) are measured, and the values for all other parameters expressed in the set of relationship equations are obtained through data fitting.

11. The system of claim 10, wherein the remaining capacity estimation equation is defined as:
$$remaining capacity {α}^{C} = {α}^{f} - {\sum }_{i = 0}^{N} {α}^{A} ( {I}_{i}^{C} , β , L , {t}_{i - 1} , {t}_{i} ) .$$

12. A method for providing remaining capacity estimation for a multi-cell battery, the multi-cell battery having a plurality of battery cells connected in accordance to a cell topology, the method comprising:
determining at least one battery type utilized in the multi-cell battery;
obtaining a remaining capacity estimation equation for each one of the at least one battery type;
mapping the cell topology to at least one of: a series system having a plurality of battery components connected in series, and a parallel system having a plurality of battery components connected in parallel; and
estimating the remaining capacity for the multi-cell battery, wherein the remaining capacity for the multi-cell battery is the minimum of the remaining capacities of the plurality of battery components when the plurality of battery components are connected in series, and the remaining capacity for the multi-cell battery is the sum of the remaining capacities of the plurality of battery components when the plurality of battery components are connected in parallel.

13. The method of claim 12, wherein at least one of the plurality of battery components is a single-cell battery.

14. The method of claim 12, wherein at least one of the plurality of battery components comprises a plurality of single-cell batteries.

15. The method of claim 12, wherein obtaining a remaining capacity estimation equation for each particular battery type further comprising:
determining a manufacturer nominated capacity for the particular battery type;
measuring an initial state of charge (SOC) for the particular battery type;
discharging a battery of the particular battery type and measuring a sequence of time-based discharge characteristics of the battery during the discharge of the battery;
measuring a total operating time of the battery and a total consumed capacity;
providing a set of relationship equations, the set of relationship equations being derived from a circuit-based battery model having a variable capacitor;
utilizing a computing module to perform data fitting of the set of relationship equations based on: the initial SOC, the manufacturer nominated capacity, the total operating time, the total consumed capacity, and the sequence of time-based discharge characteristics, the computing module being configured for determining values for a plurality of parameters of the set of relationship equations through said data fitting; and
obtaining a remaining capacity estimation equation based on the set of relationship equations after the values for the plurality of parameters are determined through said data fitting.

16. The method of claim 15, wherein the sequence of time-based discharge characteristics of the battery comprises as least one of:
a sequence of time-based discharge current of the battery;
a sequence of time-based output voltage of the battery; and
a sequence of time-based accumulated consumed capacity.

17. The method of claim 16, wherein the set of relationship equations are defined as:
$$\{ \begin{matrix}{α}^{A} ( {I}^{C} , β , L , {t}_{s} , {t}_{e} ) = {I}^{C} F ( L , {t}_{s} , {t}_{e} , β ) \\ F ( L , {t}_{s} , {t}_{e} , β ) = {t}_{s} - {t}_{e} + 2 {\sum }_{m = 1}^{∞} \frac{{e}^{- {β}^{2} {m}^{2} ( L - {t}_{s} )} - {e}^{- {β}^{2} {m}^{2} ( L - {t}_{e} )}}{{β}^{2} {m}^{2}} \\ {ϕ}^{c} = 1 - \frac{{α}^{A}}{{c}^{f}} \\ {V}^{o} ( {ϕ}^{C} ) = {a}_{1} {e}^{{a}_{2} {ϕ}^{c}} + {a}_{3} {ϕ}^{C} + {a}_{4} {ϕ}^{{C}^{2}} + {a}_{5} {ϕ}^{{C}^{3}} + {a}_{6} \\ R ( {ϕ}^{C} ) = {b}_{1} {e}^{{b}_{2} {ϕ}^{c}} + {b}_{3} {ϕ}^{C} + {b}_{4} {ϕ}^{{C}^{2}} + {b}_{5} {ϕ}^{{C}^{3}} + {b}_{6} \\ {R}^{S} ( {ϕ}^{C} ) = {d}_{1} {e}^{{d}_{2} {ϕ}^{c}} + {d}_{3} \\ {C}^{S} ( {ϕ}^{C} ) = {f}_{1} {e}^{{f}_{2} {ϕ}^{c}} + {f}_{3} \\ {R}^{L} ( {ϕ}^{C} ) = {g}_{1} {e}^{{g}_{2} {ϕ}^{c}} + {g}_{3} \\ {C}^{L} ( {ϕ}^{C} ) = {l}_{1} {e}^{{l}_{2} {ϕ}^{c}} + {l}_{3}\end{matrix}$$
and wherein the values for the initial SOC (φ^{C}), the manufacturer nominated capacity (c^{f}), the discharge current (I^{C}), the output voltage (V^{C}), the accumulated consumed capacity (α^{A}), the total operating time (L) and the total consumed capacity (α^{f}) are measured while the values for all other parameters expressed in the set of relationship equations are obtained through data fitting.

18. The method of claim 17, wherein the remaining capacity estimation equation is defined as:
$$remaining capacity {α}^{C} = {α}^{f} - {\sum }_{i = 0}^{N} {α}^{A} ( {I}_{i}^{C} , β , L , {t}_{i - 1} , {t}_{i} ) .$$
